(19) United States
(12) Patent Application Publication
(10) Pub. No.: US 2002/0109205 A1
(43) Pub. Date: Aug. 15, 2002

(54) Semiconductor device, method of creating pattern of the same, method of manufacturing the same, and apparatus for creating pattern of the same

(75) Inventors: Masatoshi Sawada, Shiga (JP); Mitsumi Ito, Kyoto (JP); Hiroyuki Tsujikawa, Shiga (JP)

Correspondence Address: McDERMOTT, WILL & EMERY, 600 13th Street, N.W., Washington, DC, 20005-3096, US

(73) Assignee: Matsushita Electric Industrial Co., Ltd.

(21) Appl. No.: 10/066,583

(22) Filed: Feb. 6, 2002

(30) Foreign Application Priority Data
Feb. 13, 2001 (JP) P2001-035564

(51) Int. Cl. H01L 29/00

(52) U.S. Cl. 257/532; 438/957

(57) ABSTRACT

By changing the shape of a bypass capacitor, inserting an inductance cell and using the bypass capacitor for each operating frequency characteristic, power source noise is absorbed to realize the stabilized operation of a circuit.

### BACKGROUND OF THE INVENTION

This invention relates to a semiconductor device, a method of creating a pattern of the same, a method of manufacturing the same and an apparatus for creating the pattern of the same, and more particularly to a semiconductor device equipped with a bypass capacitor for dealing with noise against the semiconductor device and a method of creating a pattern therefor.

With development of miniaturization of LSI and high speed of its operation speed, measures against latch-up and noise has become problematic.

Generally, in a scheme of design based on cells, a diffused area and through-hole are previously formed in a substrate cell to form a contact, and a substrate or well is fixed to a power source potential through the contact.

However, with development of miniaturization of a semiconductor device, reduction of the latch-up withstand voltage has become tangible. Addition of a substrate contact within a basic cell further increases a chip area.

In order to prevent the chip area from increasing, there has been proposed a method in which a substrate contact is arranged under a power source wiring and a capacitor with a cell bypassed is arranged between the power source wiring and ground wiring so that an increase in the area of the semiconductor device is suppressed and an improvement of the latch-up withstand voltage is realized, thereby realizing reduction of noise radiation and of malfunction due to noise invading from outside (Japanese Patent Publication No. 2000-208634).

The above method, which is a method of automatically creating the pattern of a semiconductor device, comprises the steps of creating a layout including a cell having a MIS structure and a pattern of a power source wiring and a ground wiring on a semiconductor substrate; and automatically creating the pattern of a bypass capacitor of the MIS structure, a capacitive insulating film and an electrode so as to overlap the pattern of the power source wiring, on the semiconductor substrate. According to this method, since the pattern of the power source wiring has been already created before the bypass capacitor including the diffused layer and a through-hole is formed, it can be formed using the power source wiring pattern. This facilitates the manufacturing of the semiconductor device with a high degree of integration.

An example of such a bypass capacitor is shown in FIG. 14. As seen from the figure, a bypass capacitor is formed between a poly-Si electrode (gate electrode) 71 and a substrate, and a capacitive insulating film (gate insulating film (not shown)). A diffused region is also formed in a ring shape in an area corresponding to the outer periphery of the gate electrode 71. Using a kind of bypass capacitor making the extraction and connection of a potential on the side of the substrate in the diffused region, a virtual power source wiring in the crosswise direction and a virtual power source wiring in the lengthwise direction are extracted in place of the inherent power source wiring pattern, thereby providing a bypass capacitor frame 70 including them. On the surface of the poly-Si electrode 71, a through-hole 72 for extracting the potential on the side of the poly-Si electrode is formed. In this way, a pattern of the semiconductor devices is created each of which has a bypass capacitor having a ring-shaped poly-Si electrode 71 on the power source wiring.

The method described above could reduce the power source noise which had become serious with development of miniaturization of a semiconductor device and high speed of the operating speed, but its degree is not sufficient. Therefore, in order to reduce the power source noise more surely, it has been demanded to form a bypass capacitor with a larger capacitance without increasing the occupied area. Further, the above method does not take the operating frequency into consideration, and hence cannot sufficiently reduce the noise in a semiconductor device which is operated at a specific operating frequency.

As described above, the measures of absorbing the power source noise for each of the frequency characteristics could not be realized by only provision of the poly-Si constituting the gate electrode and the bypass capacitor including a bypass capacitor diffused region to form a ring-shape outside the poly-Si and a bypass capacitor contact formed on the poly-Si.

### SUMMARY OF THE INVENTION

This invention has been accomplished under the above circumstance and intends to absorb power source noise sufficiently, thereby realizing the stable operation of a circuit.

This invention also intends to use the bypass capacitor according to an operating frequency characteristic, thereby realizing the stable operation of a circuit.

In order to achieve the above objects, in a semiconductor device according to this invention, the shape of the bypass capacitor is modified, an inductance cell is inserted and the bypass capacitor is selectively used according to an operating characteristic frequency.

Specifically, in this invention, a bypass capacitor (hereinafter referred to as a second bypass capacitor) is used in which a substrate electric potential is derived using a doughnut (ring)-shaped diffused region used in the bypass capacitor as described above, or linear diffused regions on both sides of the bypass capacitor. In addition, in this invention, another bypass capacitor in a MOS transistor structure with a diffused region below a square (or other)-shaped gate electrode is also used so that the capacitance can be increased for a unit area.

Preferably, the gate electrode has a square-shape for facilitation of automatic arrangement. Preferably, a plurality of contacts is made between the power source wiring and the gate electrode.

A pattern of the semiconductor device is automatically formed on the basis of a layout pattern.

An inductance cell is also inserted below the power source wiring.

Specifically, the semiconductor device according to this invention comprises a bypass capacitor in a MOS structure formed below a power source wiring region and having a gate electrode formed through a capacitive insulating film on a diffused region having a first conduction type, and a substrate contact for fixing a substrate potential which is arranged below a ground wiring region, and in that the bypass capacitor includes a contact in contact with the power source wiring region, which is formed on the surface of the gate electrode, and the diffused region having the first conduction type and a diffused region of the substrate contact are connected to each other.

In such a configuration, the entire opposite regions of the diffused region and gate electrode formed thereon serve as a capacitor so that the area can be used very effectively. In addition, since the potential on the substrate side is extracted through this diffused region and the resistance therefore is small, they can be integrally formed over a large area. Further, in such a structure, a capacitor having a large capacitance can be connected between the power source wiring and the ground wiring through the diffused layer with a low resistance. Accordingly, the semiconductor device can be provided which has an improved function capable of reducing unnecessary radiation noise during a high frequency operation. Further, if a contact is formed separately from the gate electrode so that the potentials at the gate electrode and the power source wiring thereon are different, a capacitor can be formed between the gate electrode and the power source wiring. Thus, a capacitor with a double-layer structure can be formed to increase the capacitance.

According to the second aspect of this invention, the diffused region having the first conduction type has the same conduction type as that of the diffused region of the substrate contact.

In such a configuration, the diffused region can be easily connected to the substrate contact, and the connecting resistance can be decreased.

In the third aspect of this invention, the semiconductor device according to the first aspect of the invention wherein the diffused region having the first conduction type has a different conduction type from that of the diffused region of the substrate contact, and the substrate contact and the diffused region having the first conduction type are connected to each other via a silicide layer formed on the surface of the diffused region of the substrate contact.

In such a configuration, when the diffused region is connected to the substrate contact, since they have different conduction types, an area with less carriers at the boundary is formed, thereby increasing the connecting resistance. However, in the second aspect, since the diffused region below the gate electrode is connected to the gate contact through the silicide layer on the surface of the diffused region, the connecting resistance can be improved, thereby providing an improved bypass capacitor.

In the fourth aspect of this invention, the semiconductor device according to any one of first to third aspect, wherein the bypass capacitor includes a capacitor region (gate region) including a square-shaped gate electrode and a gate insulating film, which are integrally formed, and a diffused region formed on the gate electrode, is provided with a diffused region so as to surround the outer periphery of the gate region (gate electrode), and connected to an upper power source wiring through a plurality of contacts formed on the surface of the gate electrode.

In such a configuration, in addition to the effects described above, since the diffused region is formed on the outer periphery of the gate electrode, the diffused region for connection can be connected in any direction irrespectively of the direction of extending the power source wiring and the flexibility of layout is also increased. Further, since the gate electrode has a square shape, a large number of gate electrodes can be arranged effectively and with increased flexibility of arrangement.

Further, since the power source wiring and the gate electrode are connected to each other through a plurality of contacts, the connecting resistance is decreased, thereby providing a capacitor having a large capacitance.

Further, in the fifth aspect of this invention, the bypass capacitor is created in a minimum graphic size of a wiring pattern rule for semiconductor manufacturing.

Such a configuration permits pattern designing to be executed automatically.

Further, in the sixth aspect of this invention, the semiconductor device according to any one of first to fifth aspect, wherein the bypass capacitor exists in a plurality of arrays below the power source wiring.

Such a configuration permits a capacitor having a large capacitance to be obtained more effectively in addition of provision of the effect described above.

In the seventh aspect of this invention, a semiconductor device according to any one of first to sixth aspect, further comprises a plurality of gate electrodes formed on the surface of a semiconductor substrate through a capacitive insulating film, a diffused region formed on the surface of the semiconductor substrate so as to encircle the outer periphery of each the gate electrodes and a substrate contact connected to a part of the diffused region, and in that the second bypass capacitor and the bypass capacitor are connected so that they can be used selectively according to a frequency characteristic.

Such a configuration permits the second bypass capacitors each with the ring-shaped diffused region for extracting the potential on the substrate side formed on the gate electrode to be arranged at necessary positions so that the bypass capacitors having the same shape can be arranged irrespectively of the direction of extending the power source wiring, and permits the bypass capacitors to be selected for each frequency characteristic, thereby providing a semiconductor device having low noise over a wide frequency band.

In the eighth aspect of this invention, a semiconductor device having a multi-layer structure wiring layers comprises an inductance cell formed to transfer between multiple wiring layers.

Such a configuration having the inductance permits noise to be reduced. Using the multiple layer wiring as it is permits automatic designing.

In the ninth aspect of this invention, a method of creating a pattern of a semiconductor device comprising: a step of creating bypass capacitor frames in which bypass capacitor frames for automatically arranging patterns of bypass capacitors are arranged on an entire chip surface;

a bypass capacitor arrangement logical operation step in which a product of a region below a power source wiring and each the bypass capacitor frames is logically operated;

a bypass capacitor arrangement re-sizing step in which logically operated data of the product of the region below the power source wiring and each the bypass capacitor frames are scaled up and down to eliminate a minute pattern; and

a logical operation step and a re-sizing step for a diffused layer for connection in which a diffused layer for connection for connecting a diffused area of the bypass capacitor below the power source and a diffused area of a substrate contact below a ground wiring is formed.

In accordance with such a method, since the pattern of the power source wiring is formed prior to creation of the pattern of the bypass capacitor, the pattern of the bypass capacitor included in the pattern of the power source wiring can be formed automatically. Namely, the semiconductor device integrated with a high degree and with low power source noise can be formed on the basis of the pattern automatically formed.

In the tenth aspect a method of creating a pattern of a semiconductor device according to ninth aspect, wherein the bypass capacitor arrangement re-sizing step is a step of enlarging/reducing the half value of the interval between the bypass capacitors to adjust the poly-Si data for forming a gate electrode, thereby increasing/decreasing the capacitance of the bypass capacitor.

Such a method permits the pattern data to be obtained easily effectively.

The eleventh aspect of this invention a method of creating a pattern of a semiconductor device comprises:

a step of creating inductance cells in which inductance cell frames for automatically arranging patterns of inductance cells are arranged on an entire chip surface;

a bypass capacitor/inductance arrangement logical operation step within a layer for each frequency characteristic in which a product of a region below a power source wiring and each the bypass inductance cell frames is logically operated; and

a bypass capacitor/inductance arrangement re-sizing step within a layer for each frequency characteristic in which logically operated data of the product of the region below the power source wiring and each the inductance cell frames are scaled up and down to eliminate a minute pattern.

In accordance with such a method, since the pattern of the power source wiring is formed prior to creation of the inductance, the pattern of the inductance included in the pattern of the power source wiring can be formed automatically. Namely, the semiconductor device integrated with a high degree and with low power source noise can be formed on the basis of the pattern automatically formed.

In the twelfth aspect of this invention, a method of manufacturing a semiconductor device using a method of creating a pattern of the semiconductor device according to any one of ninth to eleventh aspect, further comprises the step of forming the semiconductor device and the bypass capacitor on the basis of the pattern for forming the bypass capacitor.

Such a configuration permits a semiconductor device to be formed automatically.

In the thirteenth aspect of this invention, a semiconductor device according to seventh aspect, further comprises an inductance cell which transfers between multiple wiring layers in a region with at least two wiring layers, wherein the bypass capacitor and the second bypass capacitor can be selectively used for each frequency characteristic.

Such a configuration permits the inductance component to be added for each frequency characteristic as the measure against noise, and can easily provide a reliable semiconductor device which can form a pattern automatically.

In the fourteenth aspect of this invention, an apparatus of creating a pattern of a semiconductor device comprises:

means for creating bypass capacitor frames in which bypass capacitor frames for automatically arranging patterns of bypass capacitors are arranged on an entire chip surface;

a bypass capacitor arrangement logical operation means in which a product of a region below a power source wiring and each the bypass capacitor frames is logically operated;

a bypass capacitor arrangement re-sizing means in which logically operated data of the product of the region below the power source wiring and each the bypass capacitor frames are scaled up and down to eliminate a minute pattern;

a diffused area of the bypass capacitor below the power source wiring; and

a logical operation means and a re-sizing means for a diffused layer for connection in which a diffused layer for connection for connecting the diffused area of the bypass capacitor below the power source and a diffused area of a substrate contact below a ground wiring is formed.

Such an apparatus for creating a semiconductor device can automatically create the pattern of a semiconductor device with a pattern of the power source wiring formed prior to creation of the pattern of the bypass capacitor, and can easily provide hence the semiconductor device integrated with a high degree and with low power source noise can be formed on the basis of the pattern automatically formed.

In the fifteenth aspect of this invention, an apparatus of creating a pattern of a semiconductor device according to fourteenth aspect, in that the bypass capacitor arrangement re-sizing means is a means of enlarging/reducing the half value of the interval between the bypass capacitors to adjust the poly-Si data for forming a gate electrode, thereby increasing/decreasing the capacitance of the bypass capacitor.

In the sixteenth aspect of this invention, an apparatus for creating a pattern of a semiconductor device comprises:

means for creating bypass capacitor frames in which inductance cell frames for automatically arranging patterns of inductance cells are arranged on an entire chip surface;

bypass capacitor/inductance arrangement logical operation means within a layer for each frequency characteristic in which a product of a region below a power source wiring and each the bypass inductance cell frames is logically operated; and

bypass capacitor/inductance arrangement re-sizing means within a layer for each frequency characteristic in which logically operated data of the product of the region below the power source wiring and each the inductance cell frames are scaled up and down to eliminate a minute pattern.

Such an apparatus for creating a semiconductor device can automatically create the pattern of a semiconductor device with a pattern of the power source wiring previously formed prior to creation of the inductance, and hence can easily provide the semiconductor device integrated with a high degree and with low power source noise can be formed on the basis of the pattern automatically formed.

### BRIEF DESCRIPTION OF THE DRAWINGS

FIG. 1 is a flowchart showing a part of a process of designing a semiconductor device according to each of embodiments of this invention as well as details of the procedure of creating a bypass capacitor pattern;

FIG. 2 is a chip plan view of the semiconductor device according to this invention, and a plan view of the bypass capacitor formed on the entire chip surface;

FIG. 3 is a plan view of a graphic pattern with an obstacle removed from the power source wiring and a bypass capacitor;

FIG. 4 is a plan view of the bypass capacitor created using the bypass capacitor frame;

FIG. 5 is a plan view of a MOS transistor having the same polarity as that of the substrate below a power source wiring, when it has been automatically arranged as a bypass capacitor;

FIG. 6 is a plan view of a MOS transistor having a different polarity from that of the substrate below a power source wiring, when it has been automatically arranged as a bypass capacitor;

FIG. 7 is a flowchart showing a part of a process of designing a semiconductor device according to each of embodiments of this invention as well as details of the procedure of creating a bypass capacitor for each frequency characteristic;

FIG. 8 is a plan view of a bypass capacitor according to this invention and a second bypass capacitor which are used for uses;

FIGS. 9A to 9C show the inductance for a four-layer aluminum wiring, which is an example of this invention;

FIG. 10 is a plan view of an uppermost wiring created by enlarging a data removal region of an inductance cell;

FIGS. 11A and 11B are respectively a plan view and a sectional view of a four-layer wiring with an inductance inserted;

FIG. 12 is a flowchart showing a part of a process of designing a semiconductor device according to each of embodiments of this invention as well as details of the procedure of creating a bypass capacitor and an inductance for each frequency characteristic;

FIG. 13 is a plan view of a bypass capacitor according to this invention, an inductance according to this invention and a second bypass capacitor which are used for uses; and

FIG. 14 is a conventional bypass capacitor.

### DETAILED DESCRIPTION OF THE PREFERRED EMBODIMENT

Now referring to the drawings, an explanation will be given of an embodiment of this invention.

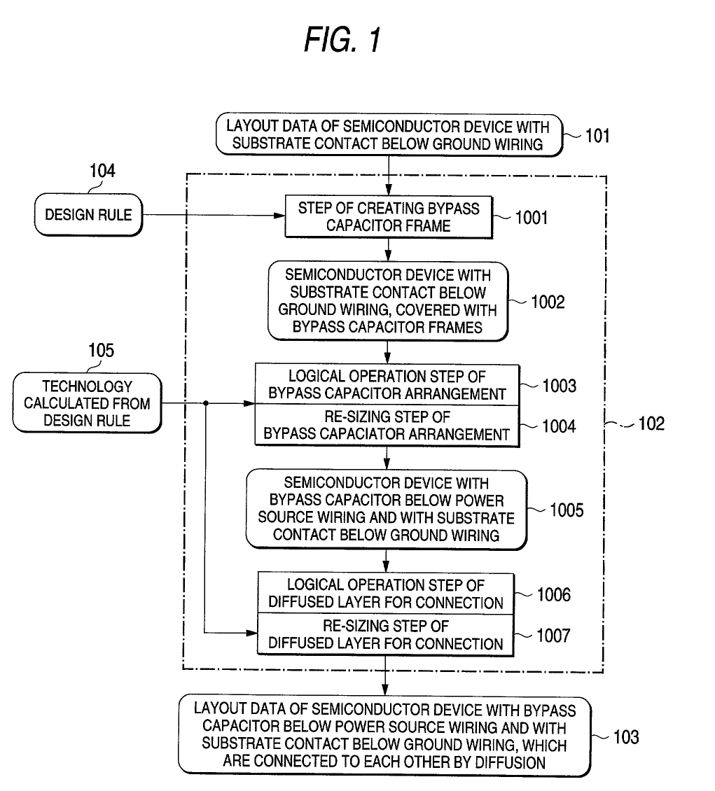

FIG. 1 is a view showing a graphic pattern creating apparatus in an embodiment of this invention. This apparatus serves to create the layout pattern of the semiconductor device equipped with a bypass capacitor in an MIS structure including a semiconductor substrate, a capacitive insulating film and an electrode. Specifically, on the basis of a design rule 104, a frame of a diffused layer for creating the bypass capacitor is formed from the data for the semiconductor device with a substrate contact below a ground wiring; and according to the technology calculated from the design rule, a semiconductor pattern is formed to execute logical operation and re-sizing processing, thereby providing the layout data for the semiconductor device having a bypass capacitor below the power source wiring and a substrate contact below the ground wiring which are connected via a diffusion (103).

In the graphic pattern creating apparatus 102, as described below, on the basis of the design rule 104, the bypass capacitor frame is created from the layout data 101 for the semiconductor device with the substrate contact below the ground wiring; according to the technology 105 calculated from the design rule, the logical operation and re-sizing step for the bypass capacitor arrangement are executed; the layout data of the semiconductor device with the bypass capacitor below the power source wiring is created, and the logical operation and re-sizing of the diffused layer for connection are executed, thereby providing the layout data for the semiconductor device with the bypass capacitor and substrate contact connected to each other via a diffused layer.

Specifically, the graphic pattern creating apparatus executes a bypass capacitor creating step 1001 of automatically creating a bypass capacitor frame on the entire surface on the basis of the design rule 104 from the layout data 101 of the semiconductor device with the substrate contact below the ground wiring; a bypass capacitor arrangement logical operation step 1003 of executing the logical operation based on the covering bypass capacitor frame and the ground wiring; and a bypass capacitor re-sizing step 1004 of resizing the bypass capacitor so as to provide an optimum size on the basis of the technology 105 calculated from the design rule, thus providing a layout data 1005 of the semiconductor device with the bypass capacitor below the power source wiring and the substrate contact below the ground wiring; a logical operation step 1006 for a diffused layer for connection for automatically arranging the diffused layer for connection on the basis of the layout data and executing the logical operation; and a re-sizing step 1007 for the diffused layer for connection of resizing the diffused layer for connection so as to provide an optimum size on the basis of the technology 105 calculated from the design rule.

The technology calculated from the design rule refers to the size of each of the components such as a cell, bypass capacitor, wiring, etc. defined by the design rule of each of the processes such as diffusion, sputtering, etching, etc.

First, the layout pattern of the semiconductor device 101 with the substrate contact below the ground wiring and design rule 104 are entered in the bypass capacitor frame creating step 1001 so that the semiconductor device 1002 covered with the bypass capacitor frame is produced from the step 1001. In the bypass capacitor frame creating step 1001, a chip size is measured, the number of bypass capacitors which can be arranged within the chip is calculated according to the design rule, and the bypass capacitor frames in the arrangement are arranged on the semiconductor device 101 with the substrate contact below the ground wiring. Thus, the semiconductor device 1002 with the substrate contact below the ground wiring, which is covered with the bypass capacitor frames, is produced.

Next, the semiconductor device with the substrate contact located below the ground wiring and covered with the bypass capacitor frames and the technology 105 calculated from the design rule are entered in the bypass capacitor arrangement logical operation step 1003 and bypass capacitor arrangement re-sizing step 1004. From the bypass capacitor arrangement logical operation step 1003 and bypass capacitor arrangement re-sizing step 1004, the semiconductor device 1005 with the bypass capacitor below the power source wiring and the substrate contact below the ground wiring is produced. In the bypass capacitor arrangement logical operation step 1003 and bypass capacitor arrangement re-sizing step 1004, a logical product of the region below the power source wiring and the bypass capacitor array is calculated so that scaling down and up for the pertinent data are performed to remove a minute pattern. The creation of the bypass capacitor in the resultant region is calculated according the technology 105 calculated from the design rule, thereby providing the semiconductor device 1005 with the bypass capacitor below the power source wiring and the substrate contact below the ground wiring.

The semiconductor device 1005 with the bypass capacitor below the power source wiring and the substrate contact below the ground wiring and the technology 105 calculated from the design rule are entered into the logical operation step 1006 for the diffused layer for connection and the re-sizing step 1007 for the diffused layer for connection. From the logical operation step 1006 for the diffused layer for connection and the re-sizing step 1007 for the diffused layer for connection, the semiconductor device 103 with the bypass capacitor below the power source wiring and the substrate contact below the ground wiring, which are connected to each other via diffusion, is produced. In the logical operation step 1006 for the diffused layer for connection and there-sizing step 1007 for the diffused layer for connection, the creation of the diffused area for connecting the diffused bypass capacitor area below the power source wiring and the diffused substrate contact below the ground wiring are calculated according to the technology 105 calculated form the design rule. As a result, the semiconductor device 103 with the bypass capacitor below the power source wiring and the substrate contact below the ground wiring, in which the bypass capacitor and ground wiring are connected to each other in the diffused area, is produced. Using the layout pattern of this semiconductor device, the semiconductor device will be actually manufactured.

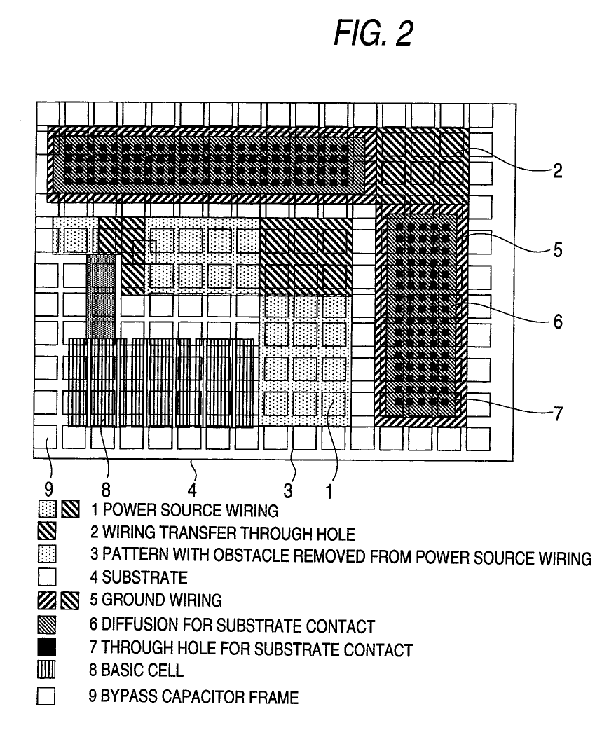

FIG. 2 is a plan view showing a part of an LSI chip and the bypass capacitor frames formed on the entire surface thereof in a graphic pattern creating step in the embodiment of this invention. The semiconductor device 1002 covered with the bypass capacitor frames 9 and the technology 105 calculated from the design rule are entered into the logical operation step 1003 for the bypass capacitor arrangement and the re-sizing step 1004 for the bypass capacitor arrangement. The wiring transfer through-hole 2 for line-to-line connection is removed from the power source wiring 1 of the semiconductor device 1002 covered with the bypass capacitor frames in the logical operation step 1003 for the bypass capacitor arrangement, thereby creating the graphic pattern 3 with an obstacle removed from the power source wiring.

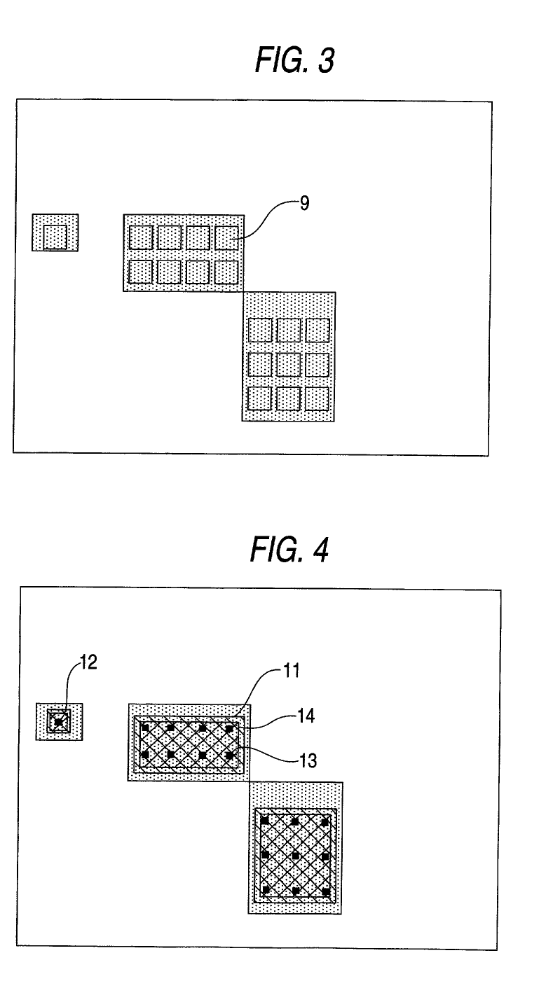

FIG. 3 is a plan view of the logical operation of the product of the graphic pattern 3 with the obstacle removed from the power source wiring in the previous item and the bypass capacitor frame 9.

The half value of the minimum width of the bypass capacitor frame 10 subjected to the logical product, which is previously defined in the technology 105, is scaled down and up to cancel the graphic pattern which has become the fine pattern in the bypass capacitor arrangement re-sizing step 1004.

FIG. 4 is a plan view of the bypass capacitor created using the bypass capacitor frame 10 obtained in the previous item. The half value of the interval between the bypass capacitor frames defined in the technology is scaled up and down to create diffusing data 11. Further, a certain value obtained from the bypass capacitor frame defined in the technology 105 is scaled down to create poly-Si data 12. A certain value obtained from the poly-Si data 12 defined in the technology 105 is scaled down to crate a through-hole 13.

In this way, a layout pattern of the semiconductor device as shown in FIG. 4 is formed which includes a second bypass capacitor with a second ring-shaped poly-Si electrode which is individually encircled by a diffused region 11, and a first bypass capacitor including a square-shaped gate electrode 14 formed on the P⁺ diffused layer 11 formed on a substrate surface through a gate insulating film 14g and a power source wiring 1 covering the gate electrode 14 through a large number of through-holes 13 formed in an array shape on the gate electrode. These first and second poly-Si electrodes 14 and 12 are formed on the resultant surface so that they are connected to the power source wiring 1 through the through-holes 13.

In this way, in the first bypass capacitor, the entire area of the opposite regions of the P⁺ diffused layer 11 and gate electrode 14 formed thereon serve as a capacitor so that the area can be used very effectively. In addition, the capacitor having a large area can be also formed between the gate electrode 14 and power source wiring 1. For this reason, the capacitor having a double layer structure can be formed so that the capacitance thereof can be increased. Further, in such a structure, a capacitor having a large capacitance can be connected between the power source wiring and the ground wiring through the diffused layer with a low resistance. Accordingly, the semiconductor device can be provided which has an improved function capable of reducing unnecessary radiation noise during a high frequency operation.

In this way, the structure of the first bypass capacitor can increase the gate area as compared with the structure of the ring-shaped gate electrode or rectangular gate electrode with diffused regions on both sides, and hence can increase the capacitor area greatly.

In this way, adoption of the new shape of the bypass capacitor with a modified shape of the electrode permits the capacitance to be made larger than that in the second bypass capacitor as described above.

In the case where there are a plurality of bypass capacitor frames in the bypass capacitor region below the power source wiring, the half value of the interval between the poly-Si's defined in the technology 105 is scaled up and down to create the poly-Si data. Such a poly-Si shape further increases the gate area, thereby increasing the capacitance.

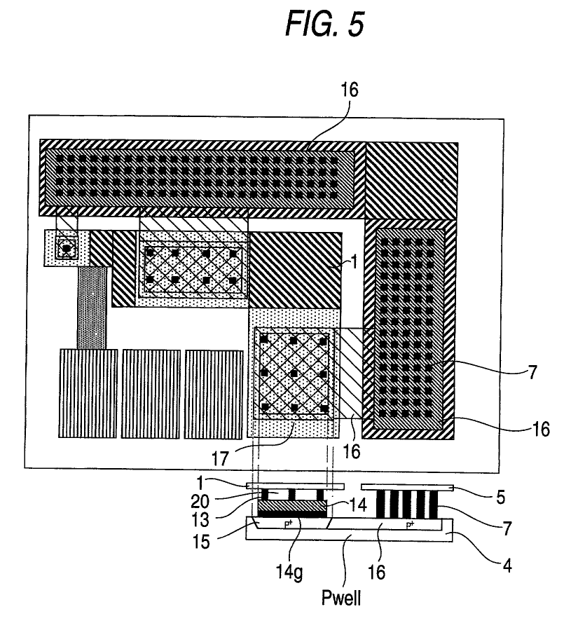

FIG. 5 is a plan view of the graphic pattern according to this invention in which the substrate contact below the ground wiring and MOS structure bypass capacitor with the diffused area having the same conduction type as that of the substrate below the power source wiring are automatically arranged and are connected to each other by diffusion. In this embodiment, since the bypass capacitor is automatically arranged below the power source wiring, the capacitance capable of reducing the power source noise without increasing the chip area can be set. Further, the diffusion 16 of the substrate contact formed below the ground wiring 5 is extended so that it is connected to the diffusion 16 of the bypass capacitor formed below the power source wiring 1. In this way, via the resistance which is lower than the high resistance of the substrate, the power source wiring 1 and the bypass capacitor are connected, and the ground wiring 5 and bypass capacitor are also connected.

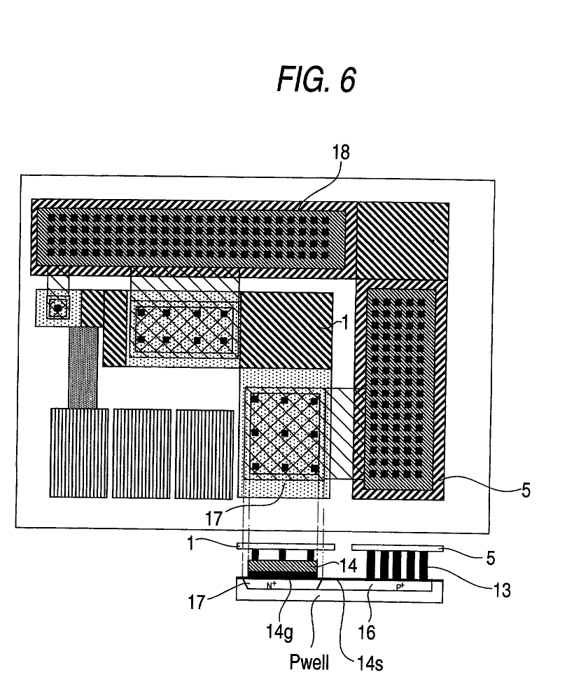

FIG. 6 is a plan view of the graphic pattern according to this invention in which the substrate contact below the ground wiring and MOS structure bypass capacitor with the diffused area having the different conduction type from the substrate below the power source wiring are automatically arranged and are connected to each other by diffusion. In this embodiment, although the diffused area 17 for forming the bypass capacitor and the diffused area 16 for the substrate contact have different polarities, a metallic silicide layer 14s formed on the surface of the diffused region 16 by the process of making silicide so that the diffused area 17 for the bypass capacitor and the diffused area 16 for the substrate contact can be connected to each other by low resistance.

In accordance with this embodiment, since the bypass capacitor is automatically arranged below the power source wiring 1, the capacitance capable of reducing the power source noise without increasing the chip area can be set. Further, since the diffused area 17 of the bypass capacitor formed below the power source wiring 1 and the diffused area 16 of the substrate contact formed below the ground wiring 5 are connected to each other via the resistance which is lower than the high resistance of the substrate, the power source wiring 1 and the bypass capacitor are connected, and the ground wiring 5 and bypass capacitor are also connected.

Incidentally, prior to forming the gate insulating film, the above metallic silicide layer 14s can be formed in the same step as the step of making silicide for the other regions. Further, when the poly-Si layer constituting the gate electrode of the bypass capacitor is silicified, the gate insulating film may be patterned simultaneously with patterning of the poly-Si, and after silicifying of the metallic layer, the non-silicified portion, i.e. the metallic layer on the side of the gate insulating film may be etched away by selective etching. Thus, the silicide layer can be formed on the substrate surface except below the gate electrode. In this case, a current can be derived without passing the PN junction, thereby providing an improved bypass capacitor.

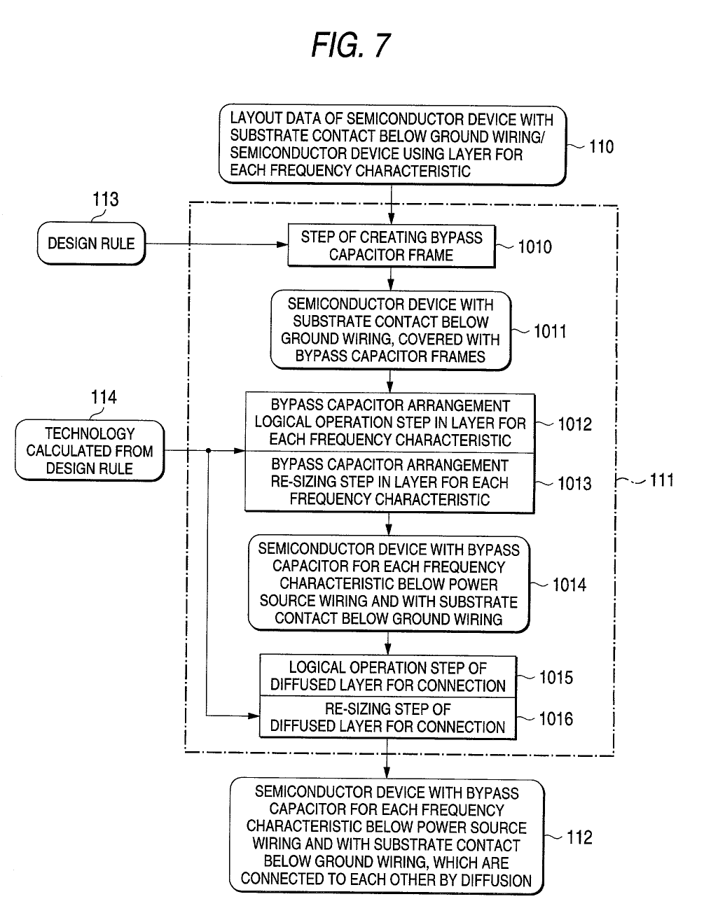

FIG. 7 shows a graphic pattern creating apparatus for using the bypass capacitor according to this invention and the second bypass capacitor for each of frequency characteristics. This apparatus executes a bypass capacitor frame creating step 1010, a bypass capacitor arrangement logical operation step 1012 with in the layer for each frequency characteristic, a bypass capacitor arrangement re-sizing step 1013 within the layer for each frequency characteristic, a logical operation step 1015 for a diffused layer for connection and a re-sizing step 1016 for the diffused layer for connection.

In this apparatus, the semiconductor device 110 using a layer for each of frequency characteristics and a design rule 113 are entered into the bypass capacitor frame creating step 1010, and the semiconductor device 1011 covered with bypass capacitor frames are produced from the bypass capacitor frame creating step 1010.

In the bypass capacitor frame creating step 1010, a chip size is measured, the number of bypass capacitors which can be arranged within the chip is calculated according to the design rule 113, and the bypass capacitor frames of the arrangement are arranged on the semiconductor device 110 with the substrate contact below the ground wiring and the semiconductor device using a layer for each of frequency characteristics. Thus, the semiconductor device 1011 with the substrate contact below the ground wiring, which is covered with the bypass capacitor frames, is produced.

Next, the semiconductor device with the substrate contact below the ground wiring, which is covered with the bypass capacitor frames and the technology 114 calculated from the design rule are entered into the bypass capacitor arrangement logical operation step 1012 within the layer for each frequency characteristic and the bypass capacitor arrangement re-sizing step 1013 within the layer for each frequency characteristic. The semiconductor device 1014 with the bypass capacitor below the power source wiring and with the substrate contact below the ground wiring is produced from the bypass capacitor arrangement logical operation step 1012 within the layer for each frequency characteristic and the bypass capacitor arrangement re-sizing step 1013 within the layer for each frequency characteristic. In the bypass capacitor arrangement logical operation step 1012 within the layer for each frequency characteristic and the bypass capacitor arrangement re-sizing step 1013 within the layer for each frequency characteristic, a logical product of the region below the power source wiring and the bypass capacitor array is calculated so that scaling down and up for the pertinent data are performed to remove a minute pattern. The creation of the bypass capacitor in the resultant region is calculated according the technology 114 calculated from the design rule, thereby providing the semiconductor device 1014 with the bypass capacitor for each frequency characteristic below the power source wiring and the substrate contact below the ground wiring.

Next, the semiconductor device 1014 with the bypass capacitor for each frequency characteristic below the power source wiring and the substrate contact below the ground wiring and the technology 114 calculated from the design rule are entered into the logical operation step 1015 for a diffused layer for connection and a re-sizing step 1016 for the diffused layer for connection. From the logical operation step 1015 for the diffused layer for connection and the re-sizing step 1016 for the diffused layer for connection, the semiconductor device 103 with the bypass capacitor for each frequency characteristic below the power source wiring and the substrate contact below the ground wiring, which are connected to each other via the diffusion, is produced. In the logical operation step 1015 for the diffused layer for connection and the re-sizing step 1016 for the diffused layer for connection, the creation of the diffused area for connecting the diffused bypass capacitor area below the power source wiring and the diffused substrate contact below the ground wiring are calculated according to the technology 114 calculated from the design rule. As a result, the semiconductor device 112 with the bypass capacitor for each frequency characteristic below the power source wiring and the substrate contact below the ground wiring, in which the bypass capacitor and ground wiring are connected to each other in the diffused area, is produced.

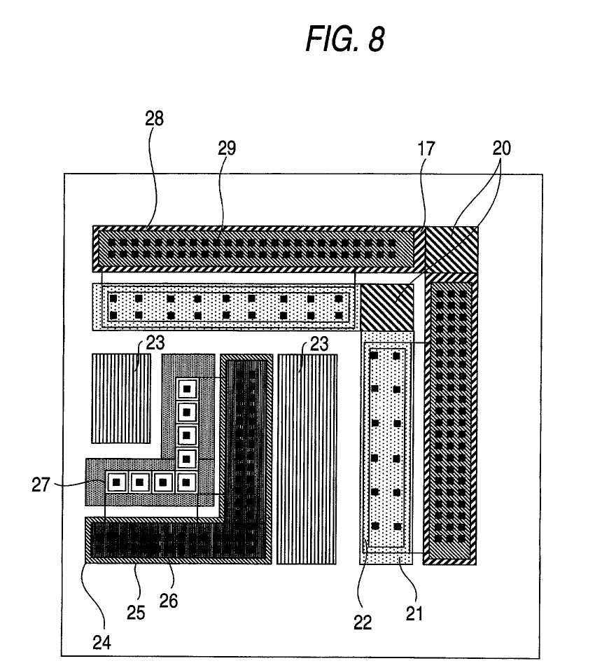

FIG. 8 is a plan view in which the bypass capacitor according to this invention and the second bypass capacitor are used according to frequency characteristics.

The bypass capacitor according to this invention has a larger capacitance than that of the second bypass capacitor. However, the bypass capacitor according to this invention, which is inferior to the second bypass capacitor in their characteristics, cannot absorb the noise at a high frequency. Using such a feature, the bypass capacitor which has a frequency characteristic enough to absorb the noise at a high frequency is arranged in the vicinity of a block cell, whereas the bypass capacitor according to this invention is arranged in the region where an increased capacitance is desired. Thus, the semiconductor device with a high performance can be automatically created.

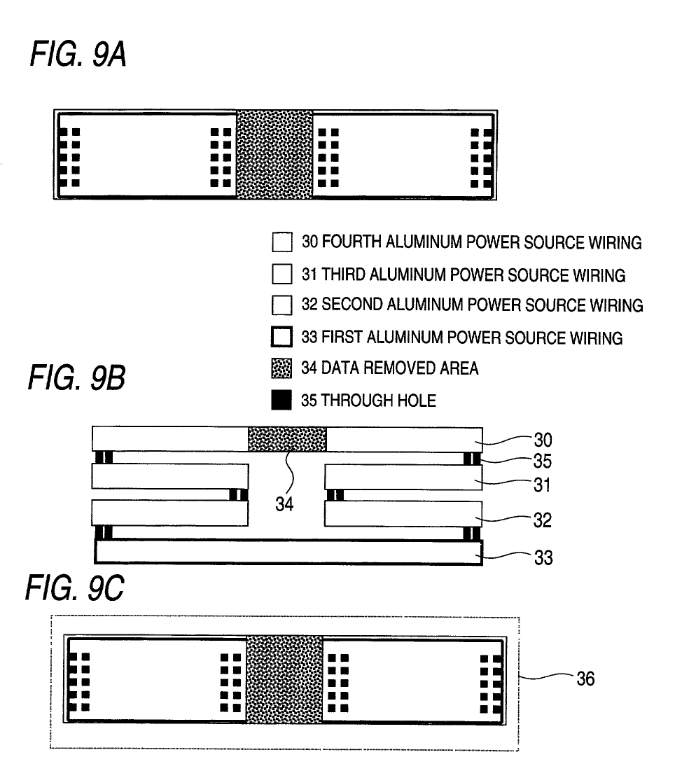

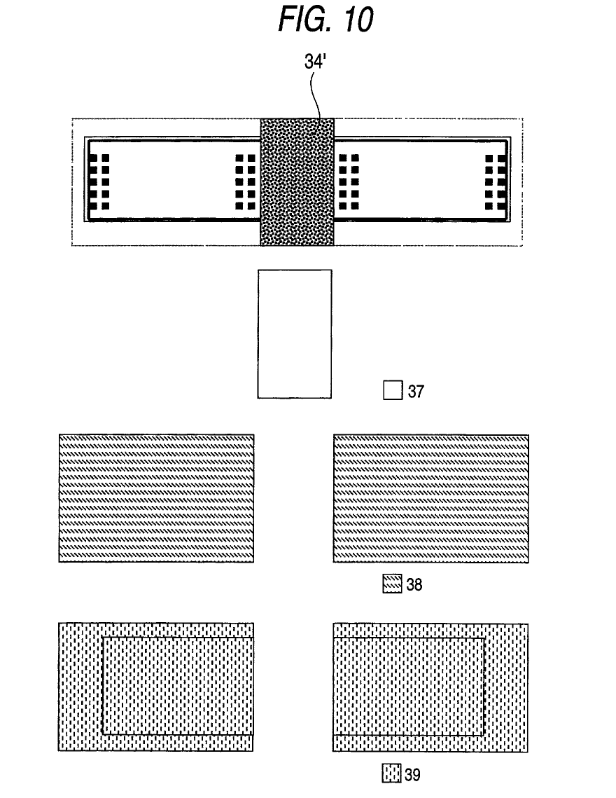

FIGS. 9A and 9B are a plan view and a sectional view of an inductance cell according to this invention, respectively. Now, the inductance cell for a four-layer aluminum wirings will be explained. An uppermost wiring layer with no wiring layer therebelow is extracted from the inductance cell including the fourth-layer aluminum wiring, third-layer aluminum wiring, second-layer aluminum wiring, first layer aluminum wiring, through-holes and data removed region. The extracted uppermost wiring layer is arranged on the uppermost wiring region 36. FIG. 9C shows a plan view of the inductance cell arranged on the uppermost wiring region 36.

FIG. 10 is a plan view showing an enlarged data removed region 36′ of the inductance cell arranged on the uppermost wiring region. The logical product of the original uppermost power source wiring and the enlarged data of the data removed region is calculated to create data 37. The logical NOT of the data 37 is calculated from the original uppermost power source wiring to create data 38. The data 39 acquired from the logical OR of the data 38 and the uppermost wiring of the inductance cell is adopted as the uppermost power source wiring.

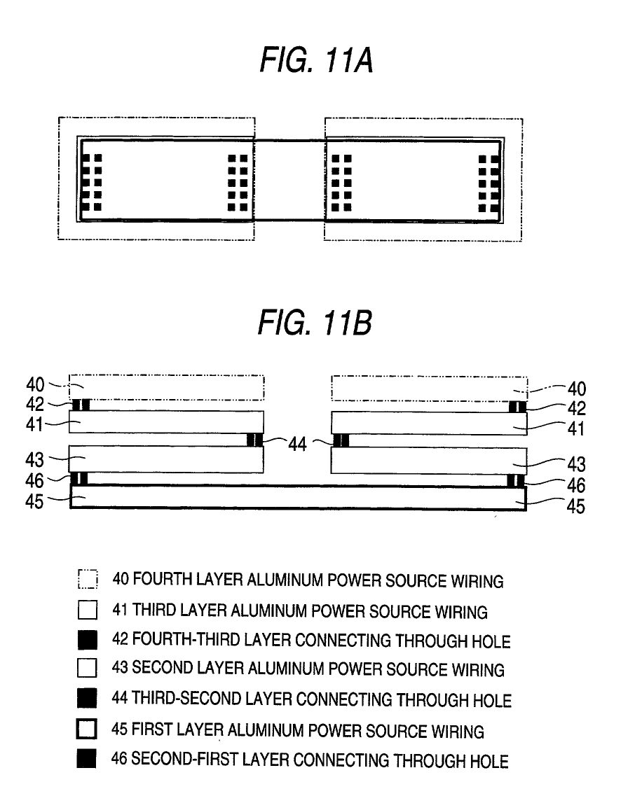

FIGS. 11A and 11B are respectively a plan view and a sectional view in which the uppermost power source wiring and the inductance cell for four wiring layers, created according to the above item, are automatically arranged.

Now, the fourth-layer wiring 40 and the third-layer wiring 41 are connected to each other via through-holes 42; the third layer wiring 41 and second layer wiring 43 are connected via through-holes 44; and the second-layer wiring 43 and the first-layer wiring 45 are connected to each other via through-holes 46. Incidentally, the through-holes 44 which connect the third-layer wiring 41 and the second-layer wiring 43 and the through-holes 42 which connect the second-layer wiring 43 and the first-layer wiring 43 are vertically arranged in lines. Such a configuration can provide an increased inductance to the maximum.

Such an inductance cell prepared for each wiring layer is automatically arranged to absorb the noise.

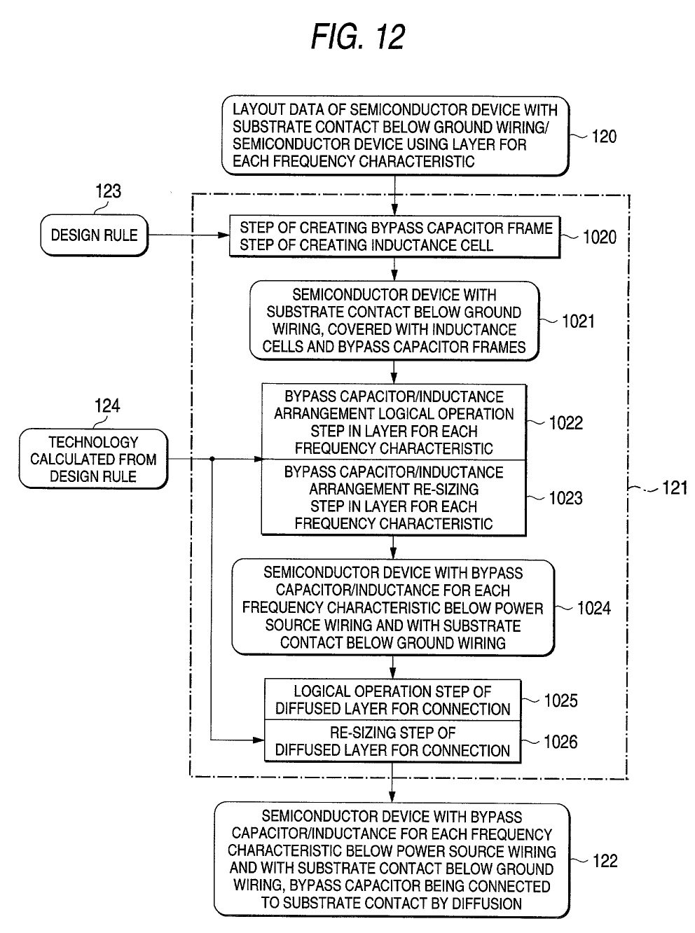

FIG. 12 shows a graphic pattern creating apparatus for using the bypass capacitor according to this invention, inductance according to this invention and the second bypass capacitor for each of frequency characteristics. This apparatus executes a bypass capacitor frame creating step/inductance cell creating step 1020, a bypass capacitor/inductance arrangement logical operation step 1022 within the layer for each frequency characteristic, a bypass capacitor/inductance arrangement re-sizing step 1023 within the layer for each frequency characteristic, a logical operation step 1025 for a diffused layer for connection and a re-sizing step 1026 for the diffused layer for connection.

In this apparatus, the semiconductor device 120 with the substrate contact below the ground wiring and the semiconductor device using a layer for each of frequency characteristics and a design rule 123 are entered into the bypass capacitor frame creating step 1020, and the semiconductor device 1021 covered with bypass capacitor frames are produced from the bypass capacitor frame creating step/inductance cell creating step 1020.

In the bypass capacitor frame creating step/inductance cell creating step 1020, a chip size is measured, the number of bypass capacitors which can be arranged within the chip is calculated according to the design rule 123, and the bypass capacitor frames of the arrangement are arranged on the semiconductor device 120 with the substrate contact below the ground wiring, or semiconductor device using a layer for each of frequency characteristics.

The number of inductance cells which can be arranged within the chip is also calculated according to the design rule 123, and the bypass capacitor frames in the arrangement is arranged on the semiconductor device 120 using a layer for each of frequency characteristics. Thus, the semiconductor device 1021 with the substrate contact below the ground wiring, which is covered with the inductance cells and the bypass capacitor frames, is produced.

Next, the semiconductor device with the substrate contact below the ground wiring, which is covered with the inductance cells and bypass capacitor frames and the technology 124 calculated from the design rule are entered into the bypass capacitor/inductance arrangement logical operation step 1022 within the layer for each frequency characteristic and the bypass capacitor/inductance arrangement re-sizing step 1023 within the layer for each frequency characteristic. The semiconductor device 1024 with the bypass capacitor and inductance below the power source wiring and with the substrate contact below the ground wiring is produced from the bypass capacitor/inductance arrangement logical operation step 1022 within the layer for each frequency characteristic and the bypass capacitor/inductance arrangement re-sizing step 1023 within the layer for each frequency characteristic. In the bypass capacitor/inductance arrangement logical operation step 1022 within the layer for each frequency characteristic and the bypass capacitor/inductance arrangement re-sizing step 1023 within the layer for each frequency characteristic, a logical product of the region below the power source wiring and the bypass capacitor array is calculated so that scaling down and up for the pertinent data are performed to remove a minute pattern. The creation of the bypass capacitor in the resultant region is calculated according the technology 114 calculated from the design rule, thereby providing the semiconductor device 1024 with the bypass capacitor for each frequency characteristic below the power source wiring and the substrate contact below the ground wiring.

As regards the inductance, the semiconductor device 1024 with the contents explained with reference to FIGS. 9, 10 and 11 which are the previous items is produced.

Next, the semiconductor device 1014 with the bypass capacitor/inductance for each frequency characteristic below the power source wiring and the substrate contact below the ground wiring and the technology 124 calculated from the design rule are entered into the logical operation step 1025 for a diffused layer for connection and a re-sizing step 1016 for the diffused layer for connection. From the logical operation step 1025 for the diffused layer for connection and the re-sizing step 1026 for the diffused layer for connection, the semiconductor device 122 with the bypass capacitor/inductance for each frequency characteristic below the power source wiring and the substrate contact below the ground wiring, which are connected to each other via the diffusion, is produced. In the logical operation step 1025 for the diffused layer for connection and the re-sizing step 1026 for the diffused layer for connection, the creation of the diffused area for connecting the diffused bypass capacitor are a below the power source wiring and the diffused substrate contact below the ground wiring are calculated ed according to the technology 124 calculated from the design rule. As a result, the semiconductor device 122 with the bypass capacitor/inductance for each frequency characteristic below the power source wiring and the substrate contact below the ground wiring, in which the bypass capacitor and substrate contact are connected to each other by diffusion, is produced.

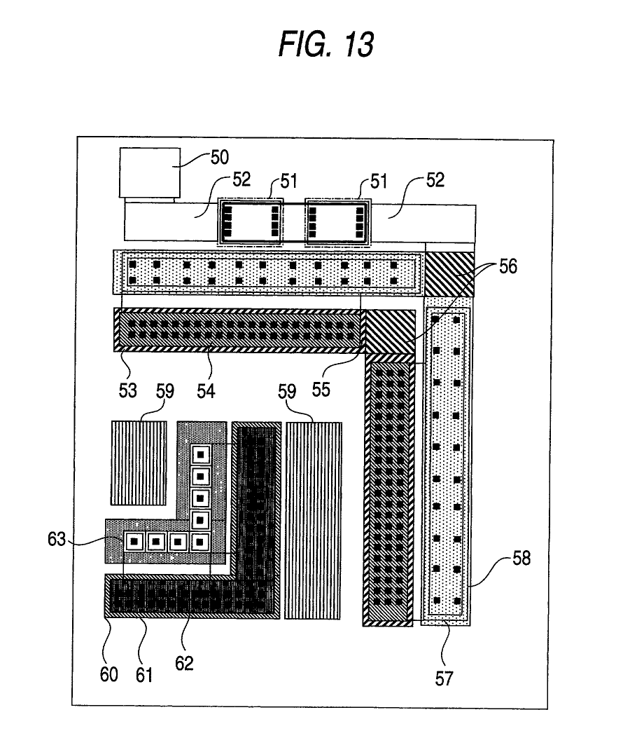

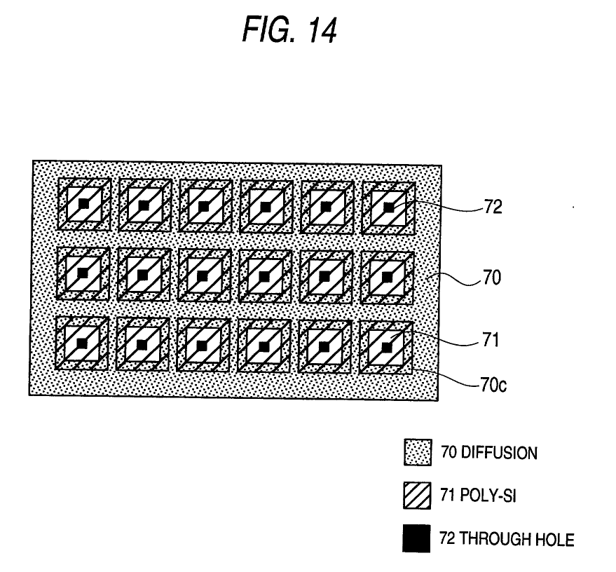

FIG. 13 is a plan view in which the bypass capacitor according to this invention, the inductance according to this invention and the second bypass capacitor are used according to frequency characteristics.

The bypass capacitor according to this invention formed on the diffused region has a larger capacitance than that of the second bypass capacitor which is formed on the substrate surface and around which a diffused region for contact is formed. However, the bypass capacitor according to this invention, which is inferior to the second bypass capacitor in their characteristics, cannot absorb the noise at a high frequency.

Using such a feature, the second bypass capacitor which has a good frequency characteristic enough to absorb the noise at a high frequency is arranged in the vicinity of a block cell, whereas the bypass capacitor according to this invention is arranged in the region where an increased capacitance is desired and the inductance according to this invention is arranged in the vicinity of the PAD where a further increased capacitance is desired. Thus, the semiconductor device with a high performance can be automatically created.

In accordance with this invention, a bypass capacitor in a MOS structure having a gate electrode formed through a capacitive insulating film is formed on a diffused region formed below a power source wiring region, a substrate contact for fixing a substrate potential is arranged below a ground wiring region, a contact in contact with the power source wiring is formed on the surface of the gate electrode, and the diffused region and a diffused region of the substrate contact are connected to each other. In such a configuration, the entire area of the opposite regions of the diffused region and gate electrode formed thereon serve as a capacitor so that the area can be used very effectively. In addition, the capacitor having a large area can be also formed between the gate electrode and power source wiring. For this reason, the capacitor having a double layer structure can be formed so that the capacitance thereof can be increased. Further, in such a structure, a capacitor having a large capacitance can be connected between the power source and the ground wiring through the diffused layer with a low resistance. Accordingly, the semiconductor device can be provided which has an improved function capable of reducing unnecessary radiation noise due to a high frequency operation.

The bypass capacitor according to this invention provides an increased capacitance, but provides a reduced diffused area to increase the resistance. This problem can be overcome by using the metallic film of silicide.

Such an effect can be also provided by interposing an inductance cell between the power source wiring and the ground wiring. This further reduces unnecessary radiation noise during a high frequency operation.

Using several kinds of bypass capacitors and inductance cells according to operating frequency characteristics can effectively absorb the power source noise and realize the stabilized operation of the circuit.

What is claimed is:

1. A semiconductor device comprising:
a bypass capacitor in a MOS structure formed below a power source wiring region and having a gate electrode formed through a capacitive insulating film on a diffused region of a first conduction type; and
a substrate contact for fixing a substrate potential which is arranged below a ground wiring region,
wherein said bypass capacitor includes a contact in contact with said power source wiring region, said contact is formed on the surface of said gate electrode,
wherein said diffused region having the first conduction type and a diffused region of said substrate contact are connected to each other.

2. The semiconductor device according to claim 1, wherein said diffused region of the first conduction type has the same conduction type as that of the diffused region of said substrate contact.

3. The semiconductor device according to claim 1,
wherein said diffused region of the first conduction type has a different conduction type from that of the diffused region of said substrate contact,
wherein said substrate contact and the diffused region having the first conduction type are connected to each other via a silicide layer formed on the surface of the diffused region of said substrate contact.

4. The semiconductor device according to claim 1,
wherein said bypass capacitor includes a gate region including the diffused region of the first conduction type and a square-shaped gate electrode integrally formed on the surface of the diffused region of the first conduction type through a capacitive insulating film,
wherein said bypass capacitor is provided with a diffused region surrounding the periphery of said gate region,
wherein said bypass capacitor is connected to the diffused region of said substrate contact through the diffused region surrounding the periphery of said gate region, and connected to an upper power source wiring through a plurality of contacts formed on the surface of said gate electrode.

5. The semiconductor device according to claim 1, wherein said bypass capacitor is created in a minimum graphic size of a wiring pattern rule for semiconductor manufacturing.

6. The semiconductor device according to claim 1, wherein said bypass capacitor is arranged in a plurality of arrays below said power source wiring.

7. The semiconductor device according to claim 1, further comprising a second bypass capacitor including:
a plurality of gate electrodes formed on the surface of a semiconductor substrate through a capacitive insulating film; a diffused region formed on said surface of the semiconductor substrate surrounding the periphery of each said gate electrodes; and
a substrate contact connected to a part of said diffused region,
wherein said second bypass capacitor and said bypass capacitor are connected to be used selectively according to a frequency characteristic.

8. A semiconductor device having a multi-layer structure wiring layers, comprising an inductance cell formed to transfer between multiple wiring layers.

9. A method of creating a pattern of a semiconductor device comprising:
a step of creating bypass capacitor frames in which bypass capacitor frames for automatically arranging patterns of bypass capacitors are arranged on an entire chip surface;
a bypass capacitor arrangement logical operation step in which a product of a region below a power source wiring and each said bypass capacitor frames is logically operated;
a bypass capacitor arrangement re-sizing step in which logically operated data of the product of said region below the power source wiring and each said bypass capacitor frames are scaled up and down to eliminate a minute pattern; and
a logical operation step and a re-sizing step for a diffused layer for connection in which the diffused layer for connection for connecting a diffused area of said bypass capacitor below said power source wiring and a diffused area of a substrate contact below a ground wiring is formed.

10. The method of creating a pattern of a semiconductor device according to claim 9, wherein said bypass capacitor arrangement re-sizing step is a step of enlarging/reducing the half value of the interval between the bypass capacitors to adjust the poly-Si data for forming a gate electrode, thereby increasing/decreasing the capacitance of the bypass capacitor.

11. A method of creating a pattern of a semiconductor device comprising:
a step of creating inductance cells in which inductance cell frames for automatically arranging patterns of inductance cells are arranged on an entire chip surface;
a bypass capacitor/inductance arrangement logical operation step within a layer for each frequency characteristic in which a product of a region below a power source wiring and each said bypass inductance cell frames is logically operated; and
a bypass capacitor/inductance arrangement re-sizing step within a layer for each frequency characteristic in which logically operated data of the product of said region below the power source wiring and each said inductance cell frames are scaled up and down to eliminate a minute pattern.

12. A method of manufacturing a semiconductor device using a method of creating a pattern of the semiconductor device according to claim 9, wherein said method of creating a pattern of the semiconductor device further comprising the step of forming the semiconductor device and the bypass capacitor on the basis of the pattern for forming the bypass capacitor.

13. The semiconductor device according to claim 7, further comprising an inductance cell which transfers between multiple wiring layers in a region with at least two wiring layers, wherein said bypass capacitor and said second bypass capacitor can be selectively used for each frequency characteristic.

14. An apparatus of creating a pattern of a semiconductor device comprising:
a bypass capacitor frames creating unit for arranging creating a bypass capacitor frames on an entire chip surface, wherein said bypass capacitor frames automatically arranges patterns of bypass capacitors;
a bypass capacitor arrangement logical operation unit in which a product of a region below a power source wiring and each said bypass capacitor frames is logically operated;
a bypass capacitor arrangement re-sizing unit in which logically operated data of the product of said region below the power source wiring and each said bypass capacitor frames are scaled up and down to eliminate a minute pattern;
a diffused area of said bypass capacitor below said power source wiring; and
a logical operation unit and a re-sizing means for a diffused layer for connection in which the diffused layer for connection for connecting the diffused area of said bypass capacitor below said power source wiring and a diffused area of a substrate contact below a ground wiring is formed.

15. The apparatus of creating a pattern of a semiconductor device according to claim 14, wherein said bypass capacitor arrangement re-sizing unit enlarges/reduces the half value of the interval between the bypass capacitors to adjust the poly-Si data for forming a gate electrode, thereby increasing/decreasing the capacitance of the bypass capacitor.

16. An apparatus for creating a pattern of a semiconductor device comprising:
an inductance cells creating unit in which inductance cell frames for automatically arranging patterns of inductance cells are arranged on an entire chip surface;
a bypass capacitor/inductance arrangement logical operation unit within a layer for each frequency characteristic in which a product of a region below a power source wiring and each said bypass inductance cell frames is logically operated; and
a bypass capacitor/inductance arrangement re-sizing unit within a layer for each frequency characteristic in which logically operated data of the product of said region below the power source wiring and each said inductance cell frames are scaled up and down to eliminate a minute pattern.
